(19) United States
(12) Patent Application Publication
(10) Pub. No.: US 2025/0006832 A1
(43) Pub. Date: Jan. 2, 2025

(54) Method of Current Sensing and Control for Interdigitated Lateral Semiconductor Device and Semiconductor Device

(71) Applicant: GaNPower International Inc., Vancouver (CA)

(72) Inventors: Zhanming LI, West Vancouver (CA); Youyi ZHAO, Vancouver (CA)

(21) Appl. No.: 18/609,342

(22) Filed: Mar. 19, 2024

Related U.S. Application Data
(60) Provisional application No. 63/511,039, filed on Jun. 29, 2023.

(51) Int. Cl. H01L 29/778; H01L 29/08

(52) U.S. Cl. CPC H01L 29/7786; H01L 28/20; H01L 29/0847

(57) ABSTRACT

The semiconductor device includes a multi-finger high electron mobility transistor (HEMT). The multi-finger HEMT includes a two-dimensional electron gas (2-DEG); a plurality of source fingers, wherein a first source finger of the plurality of source fingers extends continuously across the 2-DEG, and a second source finger of the plurality of source fingers is discontinuous across the 2-DEG; and a plurality of drain fingers, wherein the plurality of drain fingers is interdigitated with the plurality of source fingers. The second source finger is part of a current sensing element.

### PRIORITY CLAIM

This application claims priority to U.S. Provisional Application No. 63/511,039, filed Jun. 29, 2023, which is hereby incorporated by reference in its entirety.

### BACKGROUND

Current sensing of power sensing transistors is used in controlling power electronic systems. A method of current sensing includes a sensing resistor between a source and a ground. Utilizing a sensing resistor increases a risk of high power dissipation and loss of performance for high current operations. Another method of current sensing includes using multiple-finger high electron mobility transistors (HEMT). The multi-finger HEMT uses a single finger pair for sensing purposes. Using multi-finger HEMTs utilizes a device having a large main structure to sensing device width ratio in order to achieve sufficient sensing accuracy and heating disturbance. In some instances, the ratio of the main structure to sensing device for multiple-finger HEMT is in the thousands. Design rules for HEMT layouts limit a range of finger lengths, also called device width, and therefore restrict an ability to increase the main structure to sensing device ratio.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1 is a schematic diagram of a current sensor including a sense resistor on the source side of a power transistor.

FIG. 2a is a schematic diagram of a current sensor including a single finger pair in common drain circuit arrangement in a multi-finger high electron mobility transistor (HEMT).

FIG. 2b is a layout view of a current sensor including a single finger pair in common drain device layout arrangement in a multi-finger HEMT.

FIG. 3 is a schematic diagram of an integrated circuit including a broken source finger to form sensing element according to some embodiments.

FIG. 4 is a schematic diagram of an integrated circuit including a broken source finger, isolation, and 2-dimensional electron gas (2-DEG) resistors to form sensing element according to some embodiments.

FIG. 5 is a schematic diagram of an integrated circuit including a broken source finger, isolation, and resistors to form sensing element according to some embodiments.

FIG. 6 is a schematic diagram of an integrated circuit for in-line current sensing in a half-bridge arrangement according to some embodiments.

### DETAILED DESCRIPTION

The following disclosure provides many different embodiments, or examples, for implementing different features of the provided subject matter. Specific examples of components, values, operations, materials, arrangements, or the like, are described below to simplify the present disclosure. These are, of course, merely examples and are not intended to be limiting. Other components, values, operations, materials, arrangements, or the like, are contemplated. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

This description relates to a current sensing unit within an interdigitated device. The interdigitated device includes a fingers of connected to a source, or cathode, being arranged in an alternating fashion with fingers of the HEMT connected to a drain, or anode. The interdigitated device includes a device having a two-dimensional electron gas (2-DEG) conductive path. In some embodiments, the interdigitated device includes a high electron mobility transistor (HEMT). In some embodiments, the HEMT includes a III-V device. In some embodiments, the HEMT includes a gallium nitride (GaN) HEMT, an aluminum GaN (AlGaN) HEMT, or another suitable HEMT.

A sensing structure of the interdigitated device includes a discontinuity in a finger of the interdigitated device. This discontinuity defines a field effect transistor (FET) including a source, labeled S, a drain, labeled D, and a gate, labeled G. In some instances, the FET for the second structure is called a senseFET. By using interdigitated devices, a ratio of a size of a main structure of the interdigitated device to a size of a senseFET of the interdigitated device is increased in comparison with other approaches. In some instances, a ratio of the size of the main device of the interdigitated device to the senseFET is up to 10⁶ to 1. This large ratio helps to facilitate overall reduction in chip size while being able to deliver reliable functionality of current sensing.

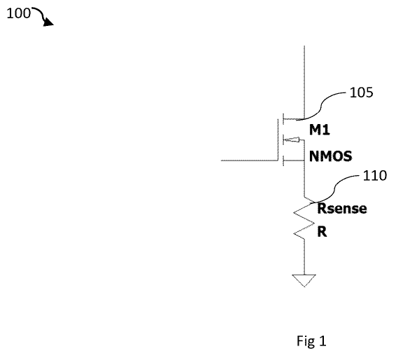

FIG. 1 is a schematic diagram of a current sensor 100 including a sense resistor 110 on the source side of a power transistor 105. The current sensor 100 includes the power transistor 105 that has a drain connected to a power source, a source connected to the sense resistor 110, and a gate for receiving a signal for selectively activating the power transistor 105. The current sensor 100 includes an n-type metal-oxide-semiconductor (NMOS) power transistor 105. In some embodiments, the power transistor 105 includes a different type of transistor, such as a p-type MOS (PMOS) or other transistor type. The current sensor 100 further includes the sense resistor 110 electrically connected between the power transistor 105 and a reference voltage, such as a ground voltage. The current sensor 100 is usable to detect a current through the sense resistor 110.

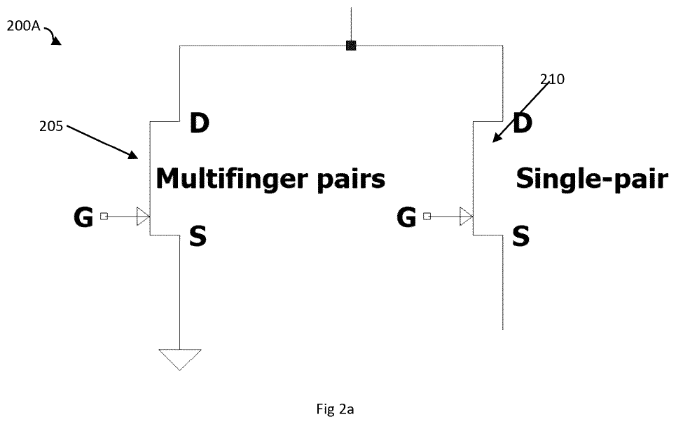

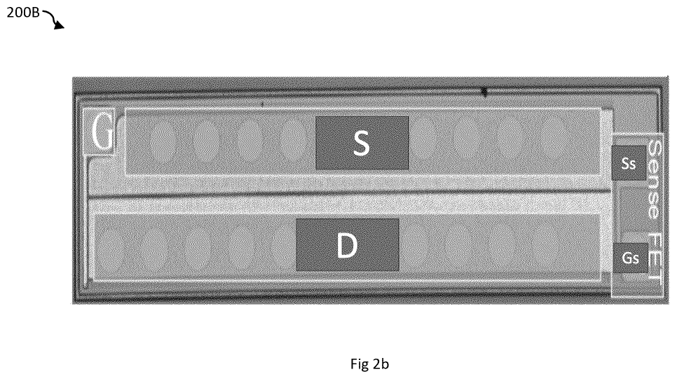

FIG. 2a is a schematic diagram of a current sensor 200A including a single finger pair 210 in common drain circuit arrangement in a multi-finger high electron mobility transistor (HEMT) 205. The current sensor 200A includes a single finger pair 210 having a source(S) connected to a detection circuit (not shown). A drain (D) of the single finger pair 210 is connected to a D of the multi-finger pairs 205. The D of the single finger pair 210 and the D of the multi-finger pairs 205 are both connected to a power source (not shown). The gate (G) of each of the single finger pair 210 and the multi-finger pairs 205 are respectively configured to selectively activate the corresponding single finger pair 210 or the multi-finger pairs 205. The S of the multi-finger pairs 210 is connected to a reference voltage, such as a ground voltage. The current sensor 200A is configured to detect the current across the single finger pair 210 to determine the current.

FIG. 2b is a layout view of a current sensor 200B including a single finger pair in common drain device layout arrangement in a multi-finger HEMT. The current sensor 200B is a layout of the current sensor 200A of FIG. 2a; and also includes a sense field effect transistor (FET) configured to detect the current passing through the single finger pair, such as single finger pair 210 (FIG. 2a). The sense FET includes a gate (Gs) and a source (Ss). In some embodiments, the sense FET is usable as the detection circuit connected to the S of the single finger pair 210 (FIG. 2a). In some embodiments, a transistor other than a FET is usable as the detection circuit.

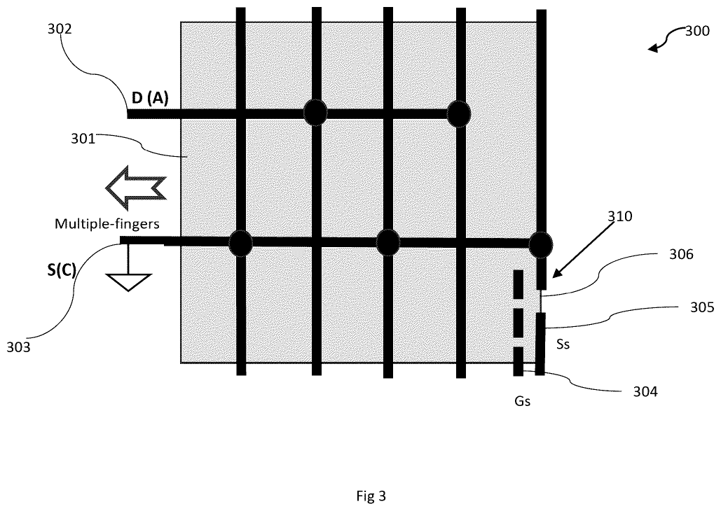

FIG. 3 is a schematic diagram of an integrated circuit 300 including a broken source finger to form sensing element according to some embodiments. The integrated circuit 300 includes a multi-finger HEMT usable to form a sensing element. The multi-finger HEMT includes a 2-DEG 301 which spans across each of the fingers of the multi-finger HEMT. The multi-finger HEMT further includes a drain connection 302 configured to connect each drain (D) finger of the multi-finger HEMT to a power source. Connections between the drain connection 302 and the D fingers of the multi-finger HEMT are indicated by circles at intersections of the D finger and the drain connection 302. In some instances, each of the D of the multi-finger HEMT are also called an anode. The multi-finger HEMT further includes a source connection 303 configured to connect each source (S) of the multi-finger HEMT to a reference voltage, such as a ground voltage. Connections between the source connection 303 and the S fingers of the multi-finger HEMT are indicated by circles at intersections of the S finger and the source connection 303. In some instances, each of the S fingers of the multi-finger HEMT are also called a cathode. The gate (G) of the multi-finger HEMT is not shown for the sake of clarity of the drawings. In some embodiments, the gate (G) of the multi-finger HEMT is configured to selectively connect the D and S of the multi-finger HEMT. In some embodiments, the G of the multi-finger HEMT is connected to a power source for maintaining the multi-finger HEMT in a permanently conductive state, i.e., the S is always electrically connected to the D of the multi-finger HEMT. The multi-finger HEMT is an inter-digitated HEMT because the S fingers alternate with the D fingers in the multi-finger HEMT.

The integrated circuit 300 further includes a sense FET 310 connected to one S finger of the multi-finger HEMT. The sense FET 310 is formed by having a gap 306 in the 2-DEG 301 adjacent to an S finger of the multi-finger HEMT. The gap 306 provides resistance for a current traveling along the S finger in order to generate a sensing voltage. The sense FET 310 further includes a sensing source (Ss) 305 and a sensing gate (Gs) 304.

In some embodiments, the gap 306 is formed by forming the multi-finger HEMT and then performing a removing process to remove a portion of the S finger. In some embodiments, the removing process includes removing at least a portion of the 2-DEG 301 as well as a portion of the S finger. In some embodiments, the removing process includes one or more etching processes, such as a wet etching or a drying etching process.

In comparison with other approaches, such as those in FIGS. 1, 2a and 2b, the integrated circuit 300 incorporates the sense FET 310 into the multi-finger HEMT. As a result, the integrated circuit 300 is able to reduce an overall size of the device in comparison with the other approaches while providing high-quality performance for current sensing.

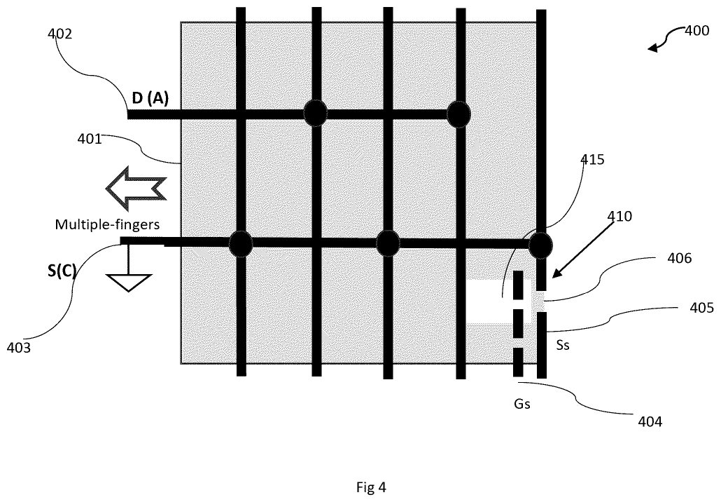

FIG. 4 is a schematic diagram of an integrated circuit 400 including a broken source finger, isolation 415, and 2-dimensional electron gas (2-DEG) resistor to form sensing element according to some embodiments. The integrated circuit 400 includes a multi-finger HEMT usable to form a sensing element. The multi-finger HEMT includes a 2-DEG 401 which spans across each of the fingers of the multi-finger HEMT. The multi-finger HEMT further includes a drain connection 402 configured to connect each drain (D) finger of the multi-finger HEMT to a power source. Connections between the drain connection 402 and the D fingers of the multi-finger HEMT are indicated by circles at intersections of the D finger and the drain connection 402. In some instances, each of the D of the multi-finger HEMT are also called an anode. The multi-finger HEMT further includes a source connection 403 configured to connect each source (S) of the multi-finger HEMT to a reference voltage, such as a ground voltage. Connections between the source connection 403 and the S fingers of the multi-finger HEMT are indicated by circles at intersections of the S finger and the source connection 403. In some instances, each of the S fingers of the multi-finger HEMT are also called a cathode. The gate (G) of the multi-finger HEMT is not shown for the sake of clarity of the drawings. In some embodiments, the gate (G) of the multi-finger HEMT is configured to selectively connect the D and S of the multi-finger HEMT. In some embodiments, the G of the multi-finger HEMT is connected to a power source for maintaining the multi-finger HEMT in a permanently conductive state, i.e., the S is always electrically connected to the D of the multi-finger HEMT. The multi-finger HEMT is an inter-digitated HEMT because the S fingers alternate with the D fingers in the multi-finger HEMT.

The integrated circuit 400 further includes a sense FET 410 connected to one S finger of the multi-finger HEMT. The sense FET 410 is formed by having a gap 406 in the 2-DEG 401 adjacent to an S finger of the multi-finger HEMT. The gap 406 provides resistance for a current traveling along the S finger in order to generate a sensing voltage. The sense FET 410 further includes a sensing source (Ss) 405 and a sensing gate (Gs) 404.

In some embodiments, the gap 406 is formed by forming the multi-finger HEMT and then performing a removing process to remove a portion of the S finger. In some embodiments, the removing process includes removing at least a portion of the 2-DEG 401 as well as a portion of the S finger. In some embodiments, the removing process includes one or more etching processes, such as a wet etching or a drying etching process.

The integrated circuit 400 further includes the isolation 415. The isolation 415 helps to electrically separate the sense FET 410 from the multi-finger HEMT. The isolation 415 extends between the Gs 404 and the gap 406, but does not extend to the edge of the 2-DEG 401 in order to maintain a high-resistance connective path between the portions of the S finger. In some embodiments, the isolation 415 includes a dielectric material, such as silicon oxide, silicon nitride, silicon carbide, or combinations thereof. In some embodiments, the isolation includes an air gap. In some embodiments, the isolation 415 includes a shallow trench isolation (STI). In some embodiments, the isolation 415 includes a deep trench isolation (DTI). In some embodiments, the isolation 415 is formed prior to forming the multi-finger HEMT. In some embodiments, the isolation 415 is formed after forming at least a portion of the multi-finger HEMT. In some embodiments, the isolation 415 is formed by removing a portion of an underlying material, such as a substrate or semiconductor layer to define a trench; and depositing a dielectric material into the trench. By utilizing isolation 415, the sense FET 410 will have a higher resistance than the sense FET 310 in the integrated circuit 300 (FIG. 3). This increase in resistance is able to be achieved without increasing a size of the integrated circuit 400 relative to the integrated circuit 300 (FIG. 3). As a result, improvement in current sensing of the integrated circuit 400 relative to the integrated circuit 300 (FIG. 3) is possible without increasing a size of the integrated circuit 400, which helps to maintaining smaller overall device size in a final product.

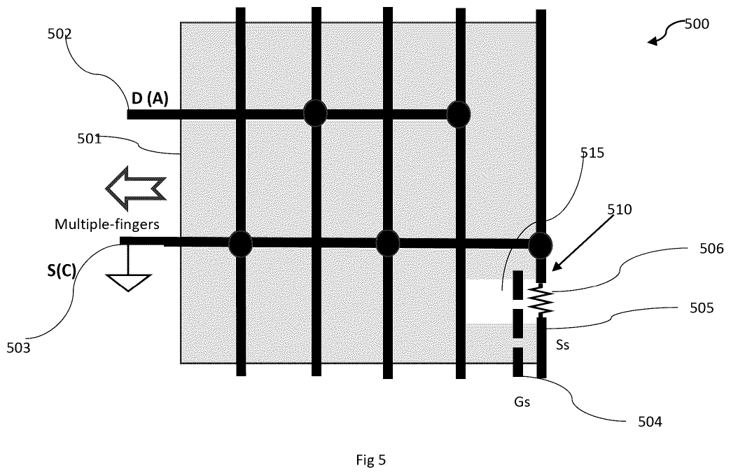

FIG. 5 is a schematic diagram of an integrated circuit 500 including a broken source finger, isolation 515, and resistor 506 to form sensing element according to some embodiments. The integrated circuit 500 includes a multi-finger HEMT usable to form a sensing element. The multi-finger HEMT includes a 2-DEG 501 which spans across each of the fingers of the multi-finger HEMT. The multi-finger HEMT further includes a drain connection 502 configured to connect each drain (D) finger of the multi-finger HEMT to a power source. Connections between the drain connection 502 and the D fingers of the multi-finger HEMT are indicated by circles at intersections of the D finger and the drain connection 502. In some instances, each of the D of the multi-finger HEMT are also called an anode. The multi-finger HEMT further includes a source connection 503 configured to connect each source (S) of the multi-finger HEMT to a reference voltage, such as a ground voltage. Connections between the source connection 503 and the S fingers of the multi-finger HEMT are indicated by circles at intersections of the S finger and the source connection 403. In some instances, each of the S fingers of the multi-finger HEMT are also called a cathode. The gate (G) of the multi-finger HEMT is not shown for the sake of clarity of the drawings. In some embodiments, the gate (G) of the multi-finger HEMT is configured to selectively connect the D and S of the multi-finger HEMT. In some embodiments, the G of the multi-finger HEMT is connected to a power source for maintaining the multi-finger HEMT in a permanently conductive state, i.e., the S is always electrically connected to the D of the multi-finger HEMT. The multi-finger HEMT is an inter-digitated HEMT because the S fingers alternate with the D fingers in the multi-finger HEMT.

The integrated circuit 500 further includes a sense FET 510 connected to one S finger of the multi-finger HEMT. The sense FET 510 is formed by having a resistor 506 electrically between portions of the broken S finger of the multi-finger HEMT. The resistor 506 provides resistance for a current traveling along the S finger in order to generate a sensing voltage. The sense FET 510 further includes a sensing source (Ss) 505 and a sensing gate (Gs) 504.

In some embodiments, the resistor 506 is formed by narrowing a portion of the broken S finger of the multi-finger HEMT. In some embodiments, a removing process removes a portion of the S finger to narrow the S finger. In some embodiments, the removing process includes removing at least a portion of the 2-DEG 501 as well as a portion of the S finger. In some embodiments, the removing process includes one or more etching processes, such as a wet etching or a drying etching process. The integrated circuit 500 in FIG. 5 includes a single resistor 506. In some embodiments, the resistor is formed by removing a portion of the S finger and depositing a resistance material to electrically connect the portions of the broken S finger. In some embodiments, the resistor 506 includes silicon chromium (SiCr) or another suitable material. In some embodiments, the integrated circuit 500 includes multiple resistors 506 connected in series or connected in parallel in order to tune a resistance for sensing the current using the integrated circuit 500.

The integrated circuit 500 further includes the isolation 515. The isolation 515 helps to electrically separate the sense FET 510 from the multi-finger HEMT. The isolation 515 extends from the Gs 404 to the resistor 506 and to the edge of the 2-DEG 501 in order to increase the resistance of the sense FET 510. In some embodiments, the isolation 515 includes a dielectric material, such as silicon oxide, silicon nitride, silicon carbide, or combinations thereof. In some embodiments, the isolation 515 includes an air gap. In some embodiments, the isolation 515 includes a shallow trench isolation (STI). In some embodiments, the isolation 515 includes a deep trench isolation (DTI). In some embodiments, the isolation 515 is formed prior to forming the multi-finger HEMT. In some embodiments, the isolation 515 is formed after forming at least a portion of the multi-finger HEMT. In some embodiments, the isolation 515 is formed by removing a portion of an underlying material, such as a substrate or semiconductor layer to define a trench; and depositing a dielectric material into the trench. By utilizing isolation 515, the sense FET 510 will have a higher resistance than the sense FET 310 in the integrated circuit 300 (FIG. 3). This increase in resistance is able to be achieved without increasing a size of the integrated circuit 500 relative to the integrated circuit 300 (FIG. 3). As a result, improvement in current sensing of the integrated circuit 500 relative to the integrated circuit 300 (FIG. 3) is possible without increasing a size of the integrated circuit 500, which helps to maintaining smaller overall device size in a final product.

In comparison with the integrated circuit 400 (FIG. 4), the integrated circuit 500 utilizes the resistor 506 in order to provide increased control over the resistance within the integrated circuit 500. However, in some embodiments, a time and expense of manufacturing the integrated circuit 500 is higher than manufacturing the integrated circuit 400, due to the formation of the resistor 506.

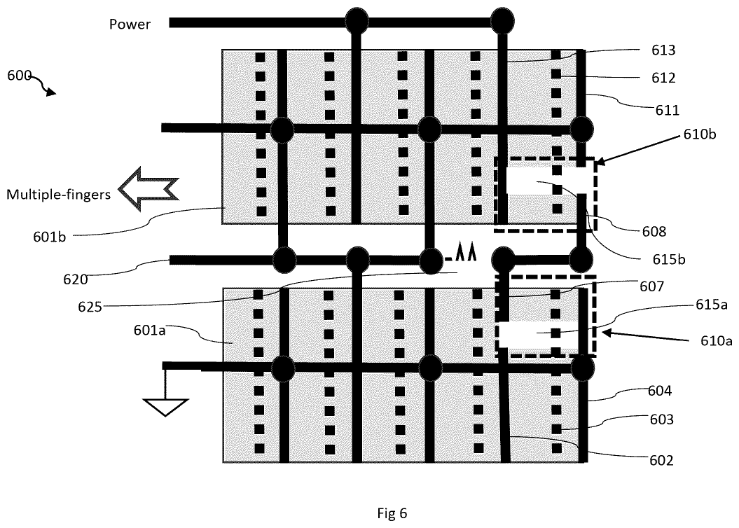

FIG. 6 is a schematic diagram of an integrated circuit 600 for in-line current sensing in a half-bridge arrangement according to some embodiments. The integrated circuit 600 includes a multi-finger HEMT separated into a high side and a low side to form a sensing element.

The multi-finger HEMT includes a low side 2-DEG 601a which spans across each of the fingers of the low side multi-finger HEMT. The low side multi-finger HEMT further includes drain fingers 602. The low side multi-finger HEMT further includes a gate 603. The low side multi-finger HEMT further includes source fingers 604. Each of the source fingers 604 are electrically connected to a reference voltage, such as a ground voltage. A sense FET 610a is also connected to the low side multi-finger HEMT. An isolation 415a is present in the sense FET 610a. The low side multi-finger HEMT further includes a broken drain finger 602 at the sense FET 610a. The isolation 615a extends from a gate 603 between the broken drain finger and an adjacent source finger 604 of the sense FET 610a. The low side multi-finger HEMT is an inter-digitated HEMT because the source fingers 604 alternate with the drain fingers 602 in the low side multi-finger HEMT.

The multi-finger HEMT includes a high side 2-DEG 601b which spans across each of the fingers of the high side multi-finger HEMT. The high side multi-finger HEMT further includes drain fingers 613. The high side multi-finger HEMT further includes a gate 612. The high side multi-finger HEMT further includes source fingers 611. Each of the drain fingers 613 are electrically connected to a power source. A sense FET 610b is also connected to the high side multi-finger HEMT. An isolation 415b is present in the sense FET 610b. The high side multi-finger HEMT further includes a broken source finger 611 at the sense FET 610b. The isolation 615b extends from a gate 612 between the broken source finger and an adjacent drain finger 613 of the sense FET 610b. The high side multi-finger HEMT is an inter-digitated HEMT because the source fingers 611 alternate with the drain fingers 613 in the high side multi-finger HEMT.

The integrated circuit 600 further includes a connection structure 620 electrically connecting the low side multi-finger HEMT to the high side multi-finger HEMT. A resistor 625 is present in the connection structure 620. In some embodiments, the resistor 625 is omitted. In some embodiments, the resistor 625 includes multiple resistors connected in parallel or connected in series.

Connections various fingers and structures are indicated by circles at intersections of the fingers and structures. The drain fingers 602 are electrically connected to the source fingers 611 by the connection structure 620. The source fingers 604 are not directly connected to the connection structure 620. The drain fingers 613 are not directly connected to the connection structure.

In some embodiments, the resistor 625 is formed by narrowing a portion of the connection structure 620. In some embodiments, a removing process removes a portion of connection structure 620 to form the resistor 625. In some embodiments, the removing process includes one or more etching process, such as a wet etching or a drying etching process. In some embodiments, the resistor 625 includes silicon chromium (SiCr) or another suitable material.

The isolations 615a and 615b help to electrically separate the respective sense FET 610a and sense FET 610b from the corresponding multi-finger HEMT. In some embodiments, the isolations 615a and 615b independently include a dielectric material, such as silicon oxide, silicon nitride, silicon carbide, or combinations thereof. In some embodiments, the isolations 615a and 615b independently include an air gap. In some embodiments, the isolations 615a and 615b independently include a shallow trench isolation (STI). In some embodiments, the isolations 615a and 615b independently include a deep trench isolation (DTI). In some embodiments, the isolations 615a and 615b are independently formed prior to forming the multi-finger HEMT. In some embodiments, the isolations 615a and 615b are independently formed after forming at least a portion of the multi-finger HEMT. In some embodiments, the isolations 615a and 615b are independently formed by removing a portion of an underlying material, such as a substrate or semiconductor layer to define a trench; and depositing a dielectric material into the trench. By utilizing isolations 615a and 615b, the respective sense FET 610a and sense FET 610b will have a higher resistance than the sense FET 310 in the integrated circuit 300 (FIG. 3).

In comparison with the integrated circuit 400 (FIG. 4), the integrated circuit 600 utilizes the low side multi-finger HEMT and the high side multi-finger HEMT in order to provide better control over resistance for sensing current. In some instances, the integrated circuit 600 is able to operate using a higher voltage power source in comparison with the integrated circuit 400 (FIG. 4).

An aspect of this description relates to a semiconductor device. The semiconductor device includes a multi-finger high electron mobility transistor (HEMT). The multi-finger HEMT includes a two-dimensional electron gas (2-DEG); a plurality of source fingers, wherein a first source finger of the plurality of source fingers extends continuously across the 2-DEG, and a second source finger of the plurality of source fingers is discontinuous across the 2-DEG; and a plurality of drain fingers, wherein the plurality of drain fingers is interdigitated with the plurality of source fingers. The second source finger is part of a current sensing element. In some embodiments, the second source finger includes a first section discontinuous from a second section, and a portion the 2-DEG provides a conductive path between the first section and the second section. In some embodiments, the semiconductor device further includes an isolation structure adjacent to the portion of the 2-DEG. In some embodiments, the semiconductor device further includes a resistor, wherein the resistor electrically connects a first section of the second source finger to a second section of the second source finger, and the first section is discontinuous with the second section. In some embodiments, the semiconductor device further includes an isolation structure adjacent to the resistor. In some embodiments, the 2-DEG is continuous across an entirety of the multi-finger HEMT. In some embodiments, the sensing element includes a gate. In some embodiments, the semiconductor device further includes an isolation structure between the gate and an adjacent source finger of the plurality of source fingers. In some embodiments, the semiconductor device further includes an isolation structure between the gate and an adjacent drain finger of the plurality of drain fingers.

An aspect of this description relates to a semiconductor device. The semiconductor device includes a high side multi-finger high electron mobility transistor (HEMT). The high side multi-finger HEMT includes a first two-dimensional electron gas (2-DEG); a first plurality of source fingers, wherein a first source finger of the first plurality of source fingers extends continuously across the first 2-DEG, and a second source finger of the first plurality of source fingers is discontinuous across the first 2-DEG; and a first plurality of drain fingers, wherein the first plurality of drain fingers is interdigitated with the first plurality of source fingers. The second source finger is part of a first current sensing element. The semiconductor device further includes a low side multi-finger HEMT. The low side HEMT includes a second 2-DEG; a second plurality of source fingers, and a second plurality of drain fingers, wherein a first drain finger of the second plurality of drain fingers extends across an entirety of the second 2-DEG, a second drain finger of the plurality of fingers is discontinuous across the second 2-DEG, and the second plurality of drain fingers is interdigitated with the second plurality of source fingers. The second drain finger is part of a second current sensing element. In some embodiments, the semiconductor device further includes a connection structure electrically connecting the high side HEMT and the low side HEMT. In some embodiments, the connection structure electrically connects the first current sensing structure and the second current sensing structure. In some embodiments, the connection structure electrically connects the second source finger to the second drain finger. IN some embodiments, the connection structure includes a resistor. In some embodiments, the semiconductor device further includes a first isolation structure, wherein the first isolation structure is adjacent to the second source finger. In some embodiments, the semiconductor device further includes a second isolation structure, wherein the second isolation structure is adjacent to the second drain finger.

An aspect of this description relates to a semiconductor device. The semiconductor device includes a multi-finger high electron mobility transistor (HEMT). The multi-finger HEMT includes a two-dimensional electron gas (2-DEG); a plurality of source fingers, wherein a first source finger of the plurality of source fingers extends continuously across the 2-DEG, and a second source finger of the plurality of source fingers is discontinuous across the 2-DEG; a plurality of drain fingers, wherein the plurality of drain fingers is interdigitated with the plurality of source fingers, and a resistance structure electrically connecting a first section of second source finger and a second section of the second source finger, wherein the first section is discontinuous with the second section, and the second source finger is part of a current sensing element. In some embodiments, the resistance structure includes a portion of the 2-DEG. In some embodiments, the resistance structure includes silicon chromium (SiCr). In some embodiments, the semiconductor device further includes an isolation structure adjacent to the resistance structure.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A semiconductor device comprising:
a multi-finger high electron mobility transistor (HEMT), wherein the multi-finger HEMT comprises:
a two-dimensional electron gas (2-DEG);
a plurality of source fingers, wherein a first source finger of the plurality of source fingers extends continuously across the 2-DEG, and a second source finger of the plurality of source fingers is discontinuous across the 2-DEG; and
a plurality of drain fingers, wherein the plurality of drain fingers is interdigitated with the plurality of source fingers, and
the second source finger is part of a current sensing element.

2. The semiconductor device of claim 1, wherein the second source finger comprises a first section discontinuous from a second section, and a portion the 2-DEG provides a conductive path between the first section and the second section.

3. The semiconductor device of claim 2, further comprising an isolation structure adjacent to the portion of the 2-DEG.

4. The semiconductor device of claim 1, further comprising a resistor, wherein the resistor electrically connects a first section of the second source finger to a second section of the second source finger, and the first section is discontinuous with the second section.

5. The semiconductor device of claim 4, further comprising an isolation structure adjacent to the resistor.

6. The semiconductor device of claim 1, wherein the 2-DEG is continuous across an entirety of the multi-finger HEMT.

7. The semiconductor device of claim 1, wherein the sensing element comprises a gate.

8. The semiconductor device of claim 7, further comprising an isolation structure between the gate and an adjacent source finger of the plurality of source fingers.

9. The semiconductor device of claim 7, further comprising an isolation structure between the gate and an adjacent drain finger of the plurality of drain fingers.

10. A semiconductor device comprising:
a high side multi-finger high electron mobility transistor (HEMT), wherein the high side multi-finger HEMT comprises:
a first two-dimensional electron gas (2-DEG);
a first plurality of source fingers, wherein a first source finger of the first plurality of source fingers extends continuously across the first 2-DEG, and a second source finger of the first plurality of source fingers is discontinuous across the first 2-DEG; and
a first plurality of drain fingers, wherein the first plurality of drain fingers is interdigitated with the first plurality of source fingers, and
the second source finger is part of a first current sensing element; and
a low side multi-finger HEMT, wherein the low side HEMT comprises:
a second 2-DEG;
a second plurality of source fingers, and
a second plurality of drain fingers, wherein a first drain finger of the second plurality of drain fingers extends across an entirety of the second 2-DEG, a second drain finger of the plurality of fingers is discontinuous across the second 2-DEG, and the second plurality of drain fingers is interdigitated with the second plurality of source fingers, and
the second drain finger is part of a second current sensing element.

11. The semiconductor device of claim 10, further comprising a connection structure electrically connecting the high side HEMT and the low side HEMT.

12. The semiconductor device of claim 11, wherein the connection structure electrically connects the first current sensing structure and the second current sensing structure.

13. The semiconductor device of claim 11, wherein the connection structure electrically connects the second source finger to the second drain finger.

14. The semiconductor device of claim 11, wherein the connection structure comprises a resistor.

15. The semiconductor device of claim 10, further comprising a first isolation structure, wherein the first isolation structure is adjacent to the second source finger.

16. The semiconductor device of claim 15, further comprising a second isolation structure, wherein the second isolation structure is adjacent to the second drain finger.

17. A semiconductor device comprising:
a multi-finger high electron mobility transistor (HEMT), wherein the multi-finger HEMT comprises:
a two-dimensional electron gas (2-DEG);
a plurality of source fingers, wherein a first source finger of the plurality of source fingers extends continuously across the 2-DEG, and a second source finger of the plurality of source fingers is discontinuous across the 2-DEG;
a plurality of drain fingers, wherein the plurality of drain fingers is interdigitated with the plurality of source fingers, and
a resistance structure electrically connecting a first section of second source finger and a second section of the second source finger, wherein the first section is discontinuous with the second section, and the second source finger is part of a current sensing element.

18. The semiconductor device of claim 17, wherein the resistance structure comprises a portion of the 2-DEG.

19. The semiconductor device of claim 17, wherein the resistance structure comprises silicon chromium (SiCr).

20. The semiconductor device of claim 17, further comprising an isolation structure adjacent to the resistance structure.
